(19) United States
(12) Patent Application Publication
(10) Pub. No.: US 2005/0287824 A1
(43) Pub. Date: Dec. 29, 2005

(54) ECR-plasma source and methods for treatment of semiconductor structures

(75) Inventors: Sergei Jurievich Shapoval, Chernogolovka (RU); Vyacheslav Aleksandrovich Tulin, Chernogolovka (RU); Valery Evgenievich Zemlyakov, Fryazino (RU); Jury Stepanovich Chetverov, Moscow (RU); Vladimir Leonidovich Gurtovoi, Chernogolovka (RU)

Correspondence Address: HOUSTON ELISEEVA, 4 MILITIA DRIVE, SUITE 4, LEXINGTON, MA, 02421, US

(73) Assignee: Obschestvo S Ogranichennoi Otvetstvennostju Epilab, Moscow (RU)

(21) Appl. No.: 11/191,554

(22) Filed: Jul. 28, 2005

Related U.S. Application Data
(63) Continuation of application No. PCT/RU04/00022, filed on Jan. 27, 2004.

(30) Foreign Application Priority Data
Jan. 28, 2003 (RU) RU2003102233

(51) Int. Cl. C23C 16/00

(52) U.S. Cl. 438/795; 118/723 MA; 427/58; 257/632

(57) ABSTRACT

The invention relates to microelectronics, more particularly, to methods of manufacturing solid-state devices and integrated circuits utilizing microwave plasma enhancement under conditions of electron cyclotron resonance (ECR), as well as to use of plasma treatment technology in manufacturing of different semiconductor structures. Also proposed are semiconductor device and integrated circuit and methods for their manufacturing. Technical result consists in improvement of reproducibility parameters of semiconductor structures and devices processed, enhancement of devices parameters, elimination of possibility of defects formation in different regions, and speeding-up of the treatment process.

### CROSS-REFERENCE TO RELATED APPLICATIONS

This application is a continuation of International Application No. PCT/RU2004/000022, filed Jan. 27, 2004, which is hereby incorporated herein in its entirety by reference, and which claims priority to Russian Application No. RU2003102233, filed Jan. 28, 2003, which is hereby incorporated herein in its entirety by reference.

### STATEMENT REGARDING FEDERALLY SPONSORED RESEARCH OR DEVELOPMENT

Not Applicable.

### REFERENCE TO A SEQUENCE LISTING, A TABLE, OR A COMPUTER PROGRAM LISTING APPENDIX SUBMITTED ON COMPACT DISC AND AN INCORPORATION-BY-REFERENCE OF THE MATERIAL ON THE COMPACT DISC

Not Applicable.

### BACKGROUND OF THE INVENTION

The invention relates to microelectronics, more particularly, to techniques for manufacturing of solid-state devices and integrated circuits utilizing microwave plasma enhancement under conditions of electron cyclotron resonance (ECR), as well as to plasma treatment techniques used in manufacturing of different semiconductor structures.

A method is known of solid-state devices and integrated circuits production (Ultra-Short 25-nm-Gate Lattice-Matched InAlAs/InGaAs HEMTs within the Range of 400 GHz Cutoff Frequency, Yoshimi Yamashita, Akira Endoh, Keisuke Shinihara, Masataka Higashiwaki, Kohki Hikosaka, Takashi Mimura, IEEE Electron device letters, vol. 22, No. 8, August 2001), comprising deposition of 200 nm thick SiO₂ layer by gas-phase plasma-assisted deposition at substrate temperature 523 K using radio frequency generator, deposition of single-layer electron-beam resist, electron-beam lithography, plasmachemical etching (PCE) using radio frequency generator, wet etching of contact layer, and deposition of second 200 nm thick SiO₂ layer by gas-phase plasma-assisted deposition at substrate temperature 523 K using radio frequency generator.

The method has a shortcoming of utilizing enhancement in silica deposition process and plasmachemical etching using radio frequency plasma, which has significantly lower density and higher particle energy as compared to microwave frequency plasma under conditions of electron cyclotron resonance and, as a result, lower etching and deposition rates and higher substrate temperature in the process of dielectric layer growth.

The most close engineering solution to the method of semiconductor structures treatment, method of production of different semiconductor devices and integrated circuits, as well as to semiconductor devices and integrated circuits is a prototype method and semiconductor device realized by its use (Sub-quarter-micron technology of field-effect transistors on pseudomorphic heterostructures with quantum well, V. G. Mokerov, Yu. V. Fedorov, A. V. Guk, V. E. Kaminsky, D. V. Amelin, L. E. Velikovsky, E. N. Ovcharenko, A. P. Lisitsky, V. Kumar, R. Muradlidkharan. Mikroelektronika (Microelectronics), 1999, vol. 28, 1, p. 3-15 (in Russian)), comprising deposition of electron-beam resist layer with a thickness of 600 nm, 60 nm of metal layer, 500 nm of SiO₂ layer, exposure and development of electron-beam resist, shaping of narrow slot in metal layer by ion etching with Ar⁺ ions having energy of 200-300 eV (0.15-0.3 micron), plasmachemical etching of a trench in SiO₂ layer, wet etching of gate trench, and sputtering of gate metals.

The drawback of the prototype lies in the use of ion etching with Ar+ ions having energy of 200-300 eV, which results in formation of radiation defects in transistor channel and, in its turn, brings about deterioration of principal transistor parameters, such as saturation current, disruptive voltages, output power, noise factor and coefficient of efficiency.

### SUMMARY OF THE INVENTION

Technical result of the proposed invention consists in
increase in reproducibility of parameters of the semiconductor structures and devices being treated,
improvement in principal parameters of devices and integrated circuits, such as cutoff working frequency, element packaging density per unit area, output power, reliability, decrease in noise level due to quality improvement and downsizing of active regions of the devices and integrated circuits,
elimination of possibility of defects formation in different regions of the structure formed,
acceleration of treatment process for different regions of the structure formed.

Technical result of the invention is accomplished by the ECR-plasma source for treatment of semiconductor structures in the process of semiconductor devices or integrated circuits manufacturing, comprising reactor with a substrate holder for placement of semiconductor structures, evacuation system ensuring ultrahigh vacuum, magnetic system, microwave generator, input of microwave radiation power, gas switching and reagent dispensing and supply system, high frequency generator with a tuner for generating constant sample self-bias, the reactor being designed in such a way that it has a nonresonant volume at frequencies 2.45 and 1.23 GHz to maintain stable discharge, and the magnetic system is made with a possibility of generating magnetic field having strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%.

The plasma source may be envisaged with a double-sided asymmetrical input of circularly polarized electromagnetic wave into plasma volume, having a shift for the value of (⅛)kλ relative to resonator's axis of symmetry, coinciding in direction with electrons rotation in the magnetic field ensuring conditions for electron cyclotron resonance, where k denotes an odd number, and λ is a wavelength.

Technical result of the invention is accomplished also in that the method of semiconductor structures treatment comprises deposition and/or etching of at least one structure layer using microwave frequency ECR-plasma source given the presence in the reactor of nonresonant volume at frequencies 2.45 and 1.23 GHz for maintenance of stable discharge with a magnetic system furnishing a magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%.

Technical result of the invention is accomplished also by manufacturing method of semiconductor devices or integrated circuits, in which semiconductor structure with active regions is formed on the substrate, conducting and/or control elements are formed having cross-sectional dimensions not exceeding 100 nm in plane, where in order to form conducting and/or control elements at least one thin layer of dielectric is deposited on the surface of the structure, resist layer is deposited, lithography and precision etching of dielectric is conducted in the regions of conducting and/or control elements location, metal(s) is sputtered and the resist is stripped, the etching and deposition of dielectric being accomplished using microwave frequency plasma enhancement under conditions of electron cyclotron resonance with radio frequency bias of the substrate in a plasma source having nonresonant reactor volume at 2.45 and 1.23 GHz frequencies with magnetic system generating magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform mode of plasma having nonuniformity of plasma density over the source cross section below 3%.

To form a T-shaped gate as a control element and/or T-shaped conductors as conducting elements or microstrip lines as dielectric layer, a layer of silicon nitride is built up at substrate temperature 293-573 K from a mixture of monosilane and nitrogen using overdense cold plasma, and precision etching is performed at substrate temperature 77-400 K also utilizing overdense cold plasma in the medium of halogen-containing gases.

To form a T-shaped transistor gate, a silicon nitride layer 100-120 nm thick is grown on GaAs, a 0.1-0.4 micron thick resist layer is deposited, and first electron-beam lithography is performed to pattern regions for sub-100 nm part of the gate, ECR-plasma etching of silicon nitride is conducted in the mixture of CF₄ and Ar or fluorine at CF₄ or fluorine flow rate 10-100 cm³/min and Ar flow rate 10-50 cm³/min at total pressure within a reactor 1-7 mTorr, second resist layer is deposited and second electron-beam lithography is performed to pattern an area for upper part of the gate having cross-sectional dimension in plane 600 nm, wet etching of transistor channel is performed, and Ti/Pt/Au metallization is conducted.

To form T-shaped conductors, polyimide layer 50-250 nm thick is deposited on substrate with active elements, silicon nitride layer 100-120 nm thick is built up on it, PMMA resist layer 0.1-0.4 micron thick is deposited and first electron-beam lithography is performed to pattern regions for sub-100 nm part of the conductor, ECR-plasma etching of silicon nitride is conducted in a mixture of CF₄ and Ar or fluorine at CF₄ or fluorine flow rate 10-100 cm³/min and Ar flow rate 10-50 cm³/min at total pressure within a reactor 1-7 mTorr, second resist layer is deposited and second electron-beam lithography is performed to form an area for upper part of the conductor having cross-sectional dimension in plane 600 nm, Ti/Pt/Au metallization is performed, and wet or ECR-plasma stripping of silicon nitride and polyimide is carried out.

Technical result of the invention is achieved also by manufacturing method of semiconductor devices or integrated circuits with a suspended microstructure, in which in order to form at least one element of device or circuit, thin dielectric layer is grown on substrate at low temperature, an electron-beam or photoresist is deposited, lithography process and precision etching of dielectric are performed, the etching and build-up of dielectric being performed using microwave frequency plasma enhancement under conditions of electron cyclotron resonance with radio frequency bias of substrate in the plasma source having nonresonant reactor volume at frequencies 2.45 and 1.23 GHz with a magnetic system generating magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%

To form suspended microstructures of uncooled bolometric matrices, polyimide layer 1-3 micron thick is deposited on substrate, silicon nitride layer is grown as dielectric layer from a mixture of monosilane and nitrogen using overdense cold plasma under conditions of electron cyclotron resonance at substrate temperature 293-573 K, a layer of heat-sensitive material is deposited, electron-beam or photolithography is performed, and precision etching is conducted using overdense cold plasma under conditions of electron cyclotron resonance at substrate temperature 77-400 K with radio frequency bias of substrate in the medium of halogen-containing gases and oxygen, after which metals sputtering is carried out and resist is stripped, the deposition of layers and etching being performed in ECR-plasma unit of ultrahigh-vacuum design.

To form air bridges of microwave transistors and integrated circuits interconnections, polyimide layer 0.5-3 micron thick is deposited on substrate, electron-beam or photolithography is performed, precision etching of polyimide surface is carried out in order to form predetermined pattern using overdense cold plasma under conditions of electron cyclotron resonance at substrate temperature 77-400 K with radio-frequency bias of the substrate in the medium of halogen-containing gases and oxygen, silicon nitride layer is grown from a mixture of monosilane and nitrogen using overdense cold plasma under conditions of electron cyclotron resonance at substrate temperature 293-573 K, metal layer is deposited, electron-beam or photolithography is performed, precision etching is carried out using overdense cold plasma under conditions of electron cyclotron resonance at substrate temperature 77-400 K with radio-frequency bias of the substrate in the medium of halogen-containing gases and oxygen, the deposition of layers and etching being performed in ECR-plasma unit of ultrahigh-vacuum design.

In order to form tuning elements of microwave transistors, solid-state or hybrid integrated circuits, polyimide layer 0.5-3 micron thick is deposited on substrate, electron-beam or photolithography is performed, precision etching of polyimide surface is carried out in order to form predetermined pattern using overdense cold plasma under conditions of electron cyclotron resonance at substrate temperature 77-400 K with radio-frequency bias of the substrate in the medium of halogen-containing gases and oxygen, silicon nitride layer is grown from a mixture of monosilane and nitrogen using overdense cold plasma under conditions of electron cyclotron resonance at substrate temperature 293-573 K, metal layer is deposited, electron-beam or photolithography is performed, precision etching is carried out using overdense cold plasma under conditions of electron cyclotron resonance at substrate temperature 77-400 K with radio-frequency bias of the substrate in the medium of halogen-containing gases and oxygen, the deposition of layers and etching being performed in ECR-plasma unit of ultrahigh-vacuum design, and the tuning of the elements being accomplished by voltage variation between substrate and upper conductor layer, with distance between substrate and upper conductor changing due to Coulomb forces, resulting in establishing of required impedance value of microwave transmission line of a transistor or an integrated circuit.

Technical result of the invention is achieved also by manufacturing method of semiconductor devices or integrated circuits, in which semiconductor structure is formed on substrate having active regions, isolation regions, metallization and passivating coating, at least one thin layer of dielectric is grown on the structure surface to form passivating coating, the build-up of dielectric being performed using microwave frequency plasma enhancement under conditions of electron cyclotron resonance with radio-frequency bias of the substrate in plasma source having nonresonant reactor volume at frequencies 2.45 and 1.23 GHz with a magnetic system generating magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%. As a semiconductor device or integrated circuit, microwave device may be manufactured having structure on base of group A_{III}B_{V} compounds, or AlGaN wide-gap semiconductor compounds, or SiC. As a passivating dielectric layer, silicon nitride layer may be formed from a mixture of monosilane and nitrogen at temperature 293-573 K using overdense cold plasma, the hydrogen bonds content (Si—H and N-H) being maintained in the range of 4-15%, and self-bias voltage—in the range of 0-50 V.

Technical result of the invention is achieved also by semiconductor device or integrated circuit with conducting and/or control elements having cross-sectional dimensions in plane not exceeding 100 nm, manufactured by method, in which semiconductor structure having active regions is formed on substrate, conducting and/or control elements having cross-sectional dimensions in plane not exceeding 100 nm are patterned, thin layer of dielectric is grown on structure surface in order to form conducting and/or control elements, resist layer is deposited, lithography and precision etching of dielectric are performed in the regions of conducting and/or control elements location, metal(s) is sputtered and resist is stripped, the etching and dielectric build-up being performed using microwave frequency plasma enhancement under conditions of electron cyclotron resonance with radio-frequency bias of the substrate in plasma source having nonresonant reactor volume at frequencies 2.45 and 1.23 GHz with a magnetic system generating magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%

Semiconductor device or integrated circuit comprises T-shaped gate as a control element and/or T-shaped conductors or microstrip lines as conducting elements, and comprises as dielectric layer a layer of silicon nitride 100-120 nm thick, grown at substrate temperature 293-573 K from a mixture of monosilane and nitrogen using overdense cold plasma, the regions of conducting and/or control elements location in dielectric being made by precision etching at substrate temperature 77-400 K also using overdense cold plasma in the medium of halogen-containing gases.

Technical result of the invention is achieved also by semiconductor device or integrated circuit with suspended microstructure, manufactured by method, in which at least one thin layer of dielectric is grown on substrate at low temperature in order to form at least one element of the device or circuit, an electron-beam or photoresist is deposited, lithography process and precision etching of dielectric are performed, the etching and growth of dielectric being performed utilizing microwave frequency plasma enhancement under conditions of electron cyclotron resonance with radio-frequency bias of the substrate in plasma source having nonresonant reactor volume at frequencies 2.45 and 1.23 GHz with a magnetic system generating magnetic field with a strength of 910-940 Gs at an internal cut of quarter-wave window of microwave radiation input on the longitudinal axis of the source and 875 Gs in the central portion of the source longitudinal axis for the length of at least 3 cm for generation of uniform plasma mode having nonuniformity of plasma density over the source cross section below 3%.

Semiconductor device or integrated circuit may comprise as layer or layers of dielectric a polyimide layer, and/or silicon nitride layer, and/or silicon oxynitride layer.

Semiconductor device or integrated circuit may comprise an uncooled bolometric matrix, or microwave transistor, or microwave integrated circuit.

### BRIEF DESCRIPTION OF THE SEVERAL VIEWS OF THE DRAWING(S)

FIG. 1 shows schematically a construction of a T-shaped gate of a field-effect transistor on gallium arsenide, produced by ECR-plasma deposition of silicon nitride and precision etching.

FIG. 2 shows schematically a construction of a T-shaped line of metal wiring.

FIG. 3 shows schematically a construction of a T-shaped micro-strip lines having transverse dimension at base in sub-100 nm range.

FIG. 4 shows schematically a construction of an element of suspended structure in uncooled bolometric matrices.

FIG. 5 shows a block diagram of an ECR-plasma unit.

FIG. 6 shows a block diagram of an ECR-plasma unit having a microwave power input with the circular polarization of the electromagnetic wave, coinciding in direction with electrons' rotation in the magnetic field.

FIG. 7 shows the results of output mower and efficiency coefficient measurements before and after passivation.

FIG. 8 shows the results of output mower and efficiency coefficient measurements before and after passivation.

FIG. 9 shows a block diagram of a double-sided asymmetrical resonator.

### DETAILED DESCRIPTION OF THE INVENTION

It has been established experimentally that ion density in the volume of ECR-plasma source runs up to 2·10¹³ cm⁻³ (and up to 4·10¹³ cm⁻³ when employing source with circular polarization of microwave wave) at energy below 25 eV. Plasma spreads in divergent magnetic field and has density in the region of the sample above 10¹² cm⁻³. Application of radio frequency bias to the sample allows to form in plasma in the neighborhood of the sample a double electrical layer (due to the difference in mobility of electrons and ions), thus allowing to control ion energy independently of parameters of ECR-plasma. This, in its turn, provides for possibility to regulate ratio of tangential and normal components of etching rates or layer growth, and composition of the layers. Geometrically, volume of ECR-plasma source is designed in such a way that it has a nonresonant volume at frequencies 2.45 and 1.23 GHz, i.e. its geometrical dimensions are not multiple to a quarter wavelength at frequencies specified. This facilitates to a great extent establishment of conditions for a stable discharge and absence of throbbing. In order to reduce losses and promote impedance matching between elements of microwave transmission line and plasma source, microwave energy is introduced through a quarter-wave quartz or ceramic window. ECR-plasma is generated in a cylindrical source and depending on the level of absorbed power and design of magnetic field may be of three modes: narrow (column), donut (ring) and uniform. The transition from narrow to uniform plasma mode is accomplished by enhancement of the magnetic field to 910-940 Gs at lower cut of input window of microwave radiation. In this case, right-hand plasma waves (RHP) does not dissipate to ECR-heating, are spread lengthwise of plasma source through overdense plasma having density considerably above critical and are transformed into whistler waves. The latter have high refractive index n>>1 (short waves) and are able to propagate through magnetized overdense plasma in radial and axial dimensions. In the region with magnetic field B=875 Gs, whistler waves are converted into electron-cyclotron waves, energy of which is spent on resonance heating of electron subsystem, resulting in steady plasma combustion under conditions of electron cyclotron resonance. For efficient excitation of ECR plasma, spatial region meeting the condition of B=875 Gs should constitute more than a half wavelength of microwave radiation. Radial profile of plasma density depends on the level of microwave power, impedance settings of microwave transmission line and magnetic field distribution. At magnetic field strength B=910-940 Gs and absorbed power above 200 W, uniform plasma mode combustion is realized at lower cut of input window of microwave radiation having density more than 10¹² cm⁻³. Such plasma spreads in divergent magnetic field as a directed flow to the region of sample location. On increase of absorbed microwave power to 500-600 W, reflected power decreases to 3-6%, thus resulting in further increase in plasma density.

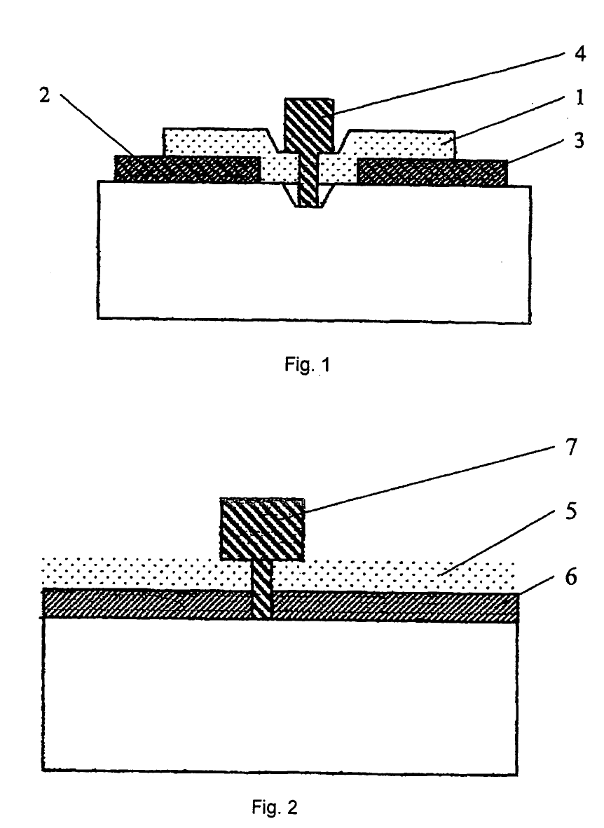

Use of such plasma allows to create sub-100 nm structures due to formation of uniform, stable in time, overdense plasma and dc self-bias owing to application of radio frequency signal to the substrate. In this case, substrate type (dielectric, metal, semiconductor) has no effect on value of dc self-bias. FIG. 1 demonstrates T-shaped gate of field-effect transistor on gallium arsenide, produced by ECR-plasma deposition of silicon nitride and precision etching in a manner described in example. Use of such gates allows to improve substantially principal parameters of transistors: transistors manufactured by the method proposed have steepness above 270 mS/mm, gain 10-13 dB at noise level 0.8-0.9 dB at 15 GHz frequency, and sustain input signal with a power up to 380 mW at gate width of 120 micron.

It has been demonstrated experimentally that utilization of ECR-plasma discharge under conditions designated in the present specification allows to build up silicon nitride or silicon oxynitride on polymeric materials, such as polyimide, at low substrate temperatures (293-323 K) without damaging the polymeric materials. Lower content of hydrogen bonds (Si—H and N—H) inherent to ECR-plasma deposition and ease of regulating hydrogen bonds ratio in silicon nitride ensure necessary mechanical (low internal mechanical stresses, low porosity) and electrical (high breakdown voltages and low leakage currents) properties of silicon nitride layer as structural material to form suspended microstructures, such as, for example, pixel sites of bolometric matrices. Said properties allow also to perform high-grade passivation of semiconductor devices. Studies have demonstrated that formation of bolometric matrices directly on wafers with multiplexer chips providing for detection and processing of signals from bolometric matrices, doesn't worsen the electrophysical parameters of integrated circuits subjected to ECR-plasma treatment. Special measurements of mechanical strength of suspended microstructures have demonstrated that they have high mechanical strength and stand successfully impact tests with acceleration above 1000×g. Matching of self-bias voltage (control of front end power and impedance of high-frequency oscillator) in order to ensure isotropic etching mode allows to strip completely “sacrificial” polyimide layers with suspended microstructures formed thereon while retaining all electrical and mechanical properties of said structures.

Besides, it has been demonstrated experimentally that utilization of ECR-plasma deposition for passivation of transistor structures on gallium arsenide and gallium-aluminium nitrides with silicon nitride with the proviso of plasma formation by the procedure described in the present application allows to improve principal parameters of transistors: output power, breakdown voltages, and coefficient of efficiency. The conditions of ECR-plasma discharge formation being satisfied, the most important factor ensuring improvement of the transistor structures parameters by passivation is matching of ratio and values of hydrogen bonds concentration in silicon nitride: silicon-hydrogen (Si—H) and nitrogen-hydrogen (N—H), assurance of oxides absence at dielectric-semiconductor interface, elimination of atomic gases diffusion, in the first place, hydrogen, into the bulk semiconductor during passivation. (Si—H) bonds in the present design and technology determine predominantly value of intrinsic charge in silicon nitride, and (N—H) bonds—value of mechanical stresses. In an application example of transistors passivation utilizing two-dimensional electron gas on basis of undoped epitaxial structures of gallium-aluminum nitride, electron density distribution across the channel is influenced by traps on semiconductor surface, intrinsic charge in passivating dielectric layer and mechanical stresses. Two-dimensional electron gas in undoped epitaxial structures of gallium-aluminum nitride is formed in the vicinity of heterojunction due to polarization effect, and such structures are characterized by high levels of piezoelectric effect. Experimental investigations and mathematical simulation have demonstrated that with hydrogen bonds concentrations in the range of 4 to 15%, it is always possible to select necessary ratio of hydrogen bonds concentrations in silicon nitride for particular semiconductor devices, thus resulting in substantial improvement in principal parameters of the transistor structures. In our example, output power at 10 GHz frequency had increased from 10 to 16 dB, and coefficient of efficiency—from 20 to 42%.

It has been also established experimentally that introduction of circularly polarized electromagnetic wave, given fulfillment of all the previously described requirements to the design of plasma source and magnetic field, allows to obtain directed plasma flow to the sample as a uniform mode with density exceeding 1.5 to 3-fold that obtained in case of utilization unpolarized microwave wave. The increase in plasma density results in corresponding increase of growth rate and etching rate during deposition and etching, correspondingly.

Proposed invention allows to manufacture wide range of solid-state devices and integrated circuits.

Following are examples of realization of the invention.

### EXAMPLE 1

An epitaxial GaAs structure is used, which has been grown by gas epitaxy of organometallic compounds. Layers have been grown on semi-insulating GaAs substrate in following order: 0.5 micron of undoped GaAs buffer layer, 150 nm of active layer doped to 10¹⁷ cm⁻³, and 50 nm of contact layer with doping concentration of 5·10¹⁸ cm⁻³. Construction of T-shaped gate is shown schematically in FIG. 1, where:
1—silicon nitride layer;
2—source;
3—drain;
4—T-shaped gate.

Sequence of T-shaped gate production operations is as follows:
after etching of mesa-structures, optical lithography is performed for patterning of Ohmic contacts, sputtering of metals forming Ohmic contact, and firing of Ohmic contacts, and silicon nitride layer 100-120 nm thick is deposited using ECR-plasma enhancement,
0.2-0.4 micron thick layer of electron-beam resist is deposited and first electron-beam lithography is performed in order to form sub-100 nm part of the gate,
ECR-plasma etching of silicon nitride is carried out in a mixture of CF₄ and Ar (30 cm³/min CF₄, 20 cm³/min Ar) at total pressure within reactor 3 mTorr,
0.4 micron thick layer of electron-beam resist is deposited and second electron-beam lithography is performed in order to form upper 600 nm part of the gate,
wet etching of the transistor channel is performed,
Ti/Pt/Au layer of gate metallization is deposited.

### EXAMPLE 2

Construction of T-shaped line of metal wiring is shown schematically in FIG. 2, where:
5-layer of silicon nitride;
6-polyimide;
7-T-shaped conductor.

Sequence of production operations in manufacturing of T-shaped conductor is as follows:
polyimide layer having thickness required by technology is deposited on the substrate,
layer of silicon nitride 100-120 nm thick is grown using ECR-plasma enhancement,
layer of electron-beam resist 0.2-0.4 micron thick is deposited, and first electron-beam lithography is performed in order to pattern sub-100 nm part of the conductor,
ECR-plasma etching of silicon nitride is carried out in a mixture of CF₄ and Ar (30 cm³/min CF₄, 20 cm³/min Ar) at total pressure within reactor 3 mTorr, and ECR-plasma etching of polyimide in oxygen medium at pressure 1 mTorr,
layer of electron-beam resist 0.4 micron thick is deposited, and second electron-beam lithography is performed in order to form upper 600 nm part of the conductor,
metallization layers are deposited as required by manufacturing process,
wet or ECR-plasma stripping of silicon nitride is performed.

### EXAMPLE 3

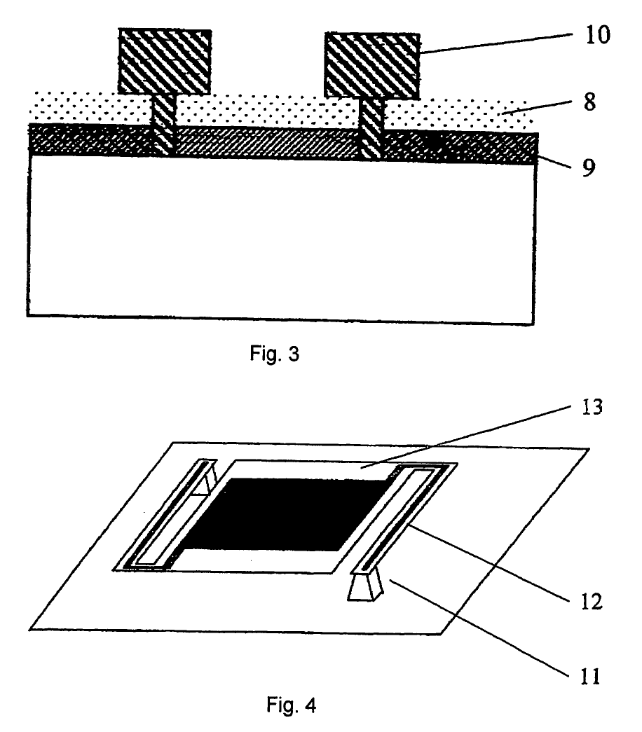

Construction of T-shaped microstrip lines having transverse dimension at base in sub-100 nm range is shown schematically in FIG. 3, where:
8—silicon nitride layer;
9—polyimide;
10—T-shaped microstrip lines.

Sequence of production operations during manufacturing of T-shaped microstrip lines having transverse dimensions at base in the sub-100 nm range is as follows:
polyimide layer 100-2000 nm thick is deposited on the substrate with active elements prefabricated,
layer of silicon nitride 100-120 nm thick is grown using ECR-plasma enhancement,
layer of electron-beam resist 0.2-0.4 micron thick is deposited, and first electron-beam lithography is performed in order to pattern sub-100 nm part of the conductor,
ECR-plasma etching of silicon nitride is performed in a mixture of CF₄ and Ar (30 cm³/min CF₄, 20 cm³/min Ar) at total pressure within reactor 3 mTorr, and ECR-plasma etching of polyimide—in oxygen medium at pressure 1 mTorr,
layer of electron-beam resist 0.4 micron thick is deposited, and second electron-beam lithography is performed in order to form upper 600 nm part of the conductor,
metallization layers are deposited, as required by manufacturing process,
wet or ECR-plasma stripping of silicon nitride and polyimide is performed.

### EXAMPLE 4

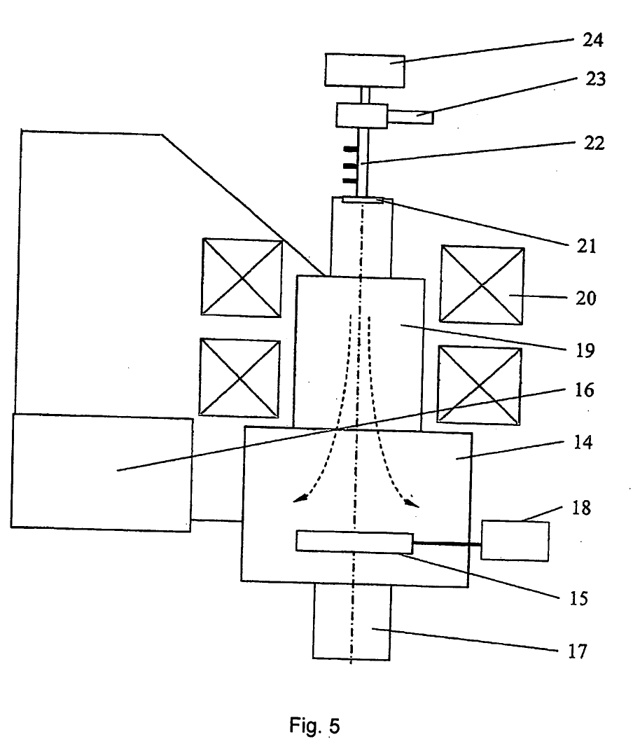

Construction of an element of suspended structure in uncooled bolometric matrices is shown schematically in FIG. 4, where:
11—support leg,
12—thermal isolation,
13—body of the suspended microstructure with heat-sensitive layer.

Sequence of production operations in manufacturing of suspended microstructures of uncooled bolometric matrices runs as follows:
polyimide layer 1-3 micron thick is deposited on substrate,
electron-beam or photolithography is performed in order to form orifices in polyimide, defining support legs of suspended structures,
silicon nitride layer is grown from a mixture of monosilane and nitrogen using overdense cold plasma under conditions of electron cyclotron resonance at substrate temperature 293-373 K,
layer of heat-sensitive material is deposited,
electron-beam or photolithography is performed to pattern geometrical dimensions and shape (body and thermal isolation) of a matrix element,
precision etching is performed using overdense cold plasma under conditions of electron cyclotron resonance at substrate temperature 77-400 K with radio-frequency bias of the substrate in the medium of halogen-containing gases and oxygen,
metals sputtering is carried out and resist layer is stripped,
“sacrificial” polyimide layer is stripped using overdense cold plasma under conditions of electron cyclotron resonance at substrate temperature 293-373 K without application of radio frequency bias of the substrate in oxygen medium.

### EXAMPLE 5

FIG. 5 shows block diagram of ECR-plasma unit.

The unit comprises metal reactor 14 fitted out with substrate holder 15, isolated off from the case, multichannel gas system 16, evacuation system 17 to create vacuum and to pump out reagents, lock and manipulator to load samples, and high-frequency generator 18 with a tuner to ensure constant self-bias required. ECR-plasma source 19 is made of metal (preferably, stainless steel or aluminum) with water-cooled walls in such a way as to provide for nonresonant volume at frequencies of 2.45 and 1.23 GHz to maintain stable discharge. Magnetic system 20 based on a pair of Helmholtz coils is made in such a way as to ensure value of magnetic field in the range of 910-940 Gs at lower cut of quarter-wave dielectric window of microwave power input on the axis of the source, and 875 Gs on the longitudinal axis of the source in its central portion for the length of at least 3 cm. Dielectric quarter-wave window 21 is located in the end portion of the source and is hermetically sealed in order to ensure input of microwave power and create vacuum required. Plasma-forming gas is introduced from this same end of the source through distributed circular inlet. To the quarter-wave window, microwave transmission line is connected comprising tuner 22, circulator 23 to protect magnetron from the reflected wave, and monitor 24 to measure direct and reflected power and magnetron in the case.

### EXAMPLE 6

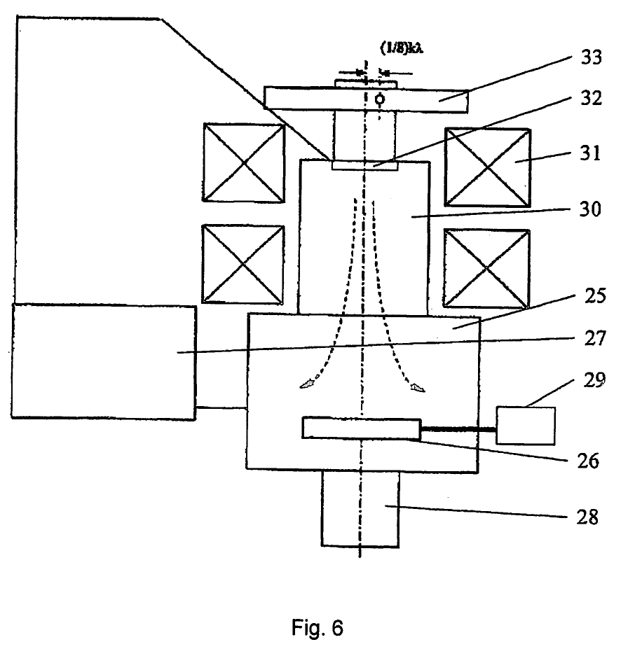

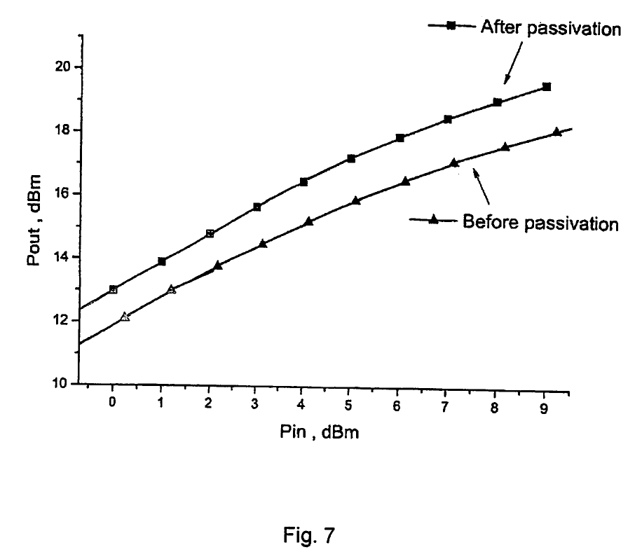

FIG. 6 shows block diagram of ECR-plasma unit having microwave power input with circular polarization of electromagnetic wave, coinciding in direction with electrons rotation in the magnetic field.

The unit comprises metal reactor 25, fitted out with a substrate holder 26 isolated from the case, multichannel gas system 27, evacuation system 28 to create vacuum and to pump out the reagents, lock and manipulator to load samples, and high-frequency generator 29 with a tuner to provide for constant self-bias required. ECR-plasma source 30 is made of metal (preferably, stainless steel or aluminum) with water-cooled walls in such a way as to provide for nonresonant volume at frequencies of 2.45 and 1.23 GHz to maintain stable discharge. Magnetic system 31 based on a pair of Helmholtz coils is made in such a way as to provide value of the magnetic field in the range of 910-940 Gs at lower cut of quarter-wave dielectric window 32, and 875 Gs on the longitudinal axis of the source in its central portion for the length of at least 3 cm. Dielectric quarter-wave window 32 is located in the end portion of the source and is hermetically sealed to ensure input of microwave power and to provide vacuum required. Plasma-forming gas is introduced from this same end of the source. To the quarter-wave window, a composite resonator 33 is connected comprising cavity and ring resonators. Input of microwave radiation into ring resonator is accomplished with a shift relative to its axis of symmetry by a length multiple to one eighth of microwave radiation wavelength, resulting in circular polarization of microwave radiation introduced into the reactor, coinciding in direction with electrons rotation in the magnetic field.

### EXAMPLE 7

Microwave transistor structure with two gates having dimensions of 37.5×0.3 micron is produced using undoped AlGaN/GaN epitaxial structure on sapphire substrate. After that, passivating silicon nitride is grown, providing for improvement in principal parameters of transistor structures, by following sequence of production steps:
1. Cleaning of wafer is carried out in a mixture of isopropyl alcohol and acetone in the ratio of 1:1 for 15 min.
2. Washing of wafer is carried out in deionized water in a three-stage bath.
3. The wafer is loaded into ECR-plasma reactor and processed in a mixture of argon, oxygen and carbon tetrafluoride at rate flows ratio of 1:1:1 and total pressure of 2.5 mTorr for 25 s. Level of absorbed microwave power amounts to 300 W, substrate temperature 300° C.
4. Reactor evacuation is performed for a 10 min. to remove residual gases.
5. Reactor is filled with nitrogen up to a pressure of 0.5 mTorr.
6. ECR-plasma is fired at absorbed power level 500 W and the wafer with transistor structures is processed for a 10 min. in nitrogen plasma.
7. 20% mixture of monosilane and argon is introduced into the reactor up to a total pressure of 2.6 mTorr in the course of 30 min. Silicon nitride layer is grown with a thickness of 100 nm.
8. The wafer is removed from the reactor and opening of contact windows is performed by photolithography and plasma etching.
9. Output power and coefficient of efficiency of the transistor structures at 10 GHz frequency are measured using microwave probe device.

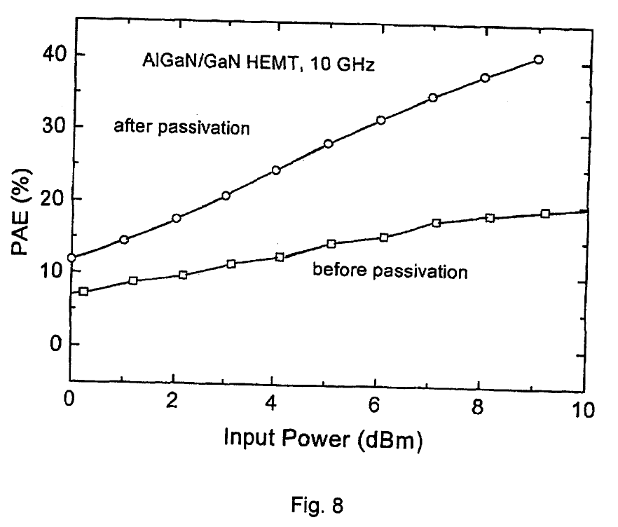

Results of the measurements before and after passivation are shown in FIGS. 7 and 8. Increase in output power and efficiency coefficient of transistor structures due to passivation has been observed.

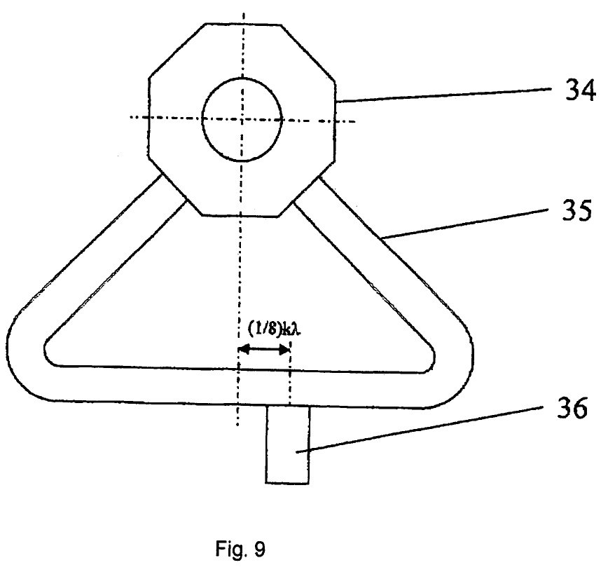

FIG. 9 shows block diagram of a double-sided asymmetrical resonator, where:
34—cavity resonator with two inputs,
35—phase-shifting arms of ring resonator,
36—asymmetrical input of microwave power.

In cavity resonator, circular polarization of microwave radiation is achieved by electromagnetic radiation being introduced into cavity resonator through mutually perpendicular inputs using two phase-shifting arms of the ring resonator (two coaxial cables or waveguides). Power input from the microwave generator is shifted by value of (⅛)kλ with regard to symmetry axis of ring resonator, where k denotes an odd number, and k is a wavelength. Circular polarization is created due to a phase shift of electromagnetic waves, introduced to cavity resonator through two arms of ring resonator, and having wavelengths differing by (¼)kλ. In this case, microwave radiation with a circular polarization coinciding in direction with electrons rotation in the magnetic field, supplies additional energy to electrons, thus increasing plasma density within source volume. Increase in plasma density results in enhancement of layer growth rate or etching rate as much as 1-4 times depending on pressure within chamber and reagents flow ratio.

1. ECR-plasma source for treatment of semiconductor structures in semiconductor devices or integrated circuits manufacturing, comprising
a reactor comprising
a substrate holder capable of holding semiconductor structures,
an evacuation system capable of providing ultrahigh vacuum,
a magnetic system,
a microwave generator,
an microwave radiation power input comprising
a quarter-wave window,
a gas switching and reagent dispensing and supply system, and
a high frequency generator comprising
a tuner capable of generating constant sample self-bias,
the reactor having a non-resonant volume at the frequency of 2.45 and 1.23 GHz,
the reactor being capable of maintaining a stable discharge,
the source having a longitudinal axis,
the magnetic system being capable of creating a magnetic field of 910-940 Gs at an internal cross-section of the quarter-wave window on the longitudinal axis,
the magnetic system being capable of creating a magnetic field of 875 Gs in the central portion of the longitudinal axis for the length of at least 3 cm,
the source being capable of generating a uniform plasma mode having a non-uniformity of plasma density below 3% over a cross-section of the source.

2. The ECR-plasma source of claim 1, further comprising
a resonator having a symmetry axis and
a double-sided asymmetrical input of circularly polarized electromagnetic wave into plasma, the input being shifted by (⅛) kλ with respect to the symmetry axis of the resonator, the wave coinciding in direction with electrons rotation in the magnetic field capable of establishing conditions for electron cyclotron resonance,
where k denotes an odd number, and X is the wavelength of the wave.

3. A method of treatment of semiconductor structures, comprising
growing at least one structure layer using a microwave frequency ECR-plasma source,
the ECR-plasma source comprising
a reactor and
a magnetic system,
the reactor having a non-resonant volume at the frequency of 2.45 and 1.23 GHz,
the reactor being capable of maintaining a stable discharge,
the source having a longitudinal axis,
the magnetic system being capable of creating a magnetic field of 910-940 Gs at an internal cross-section of the quarter-wave window on the longitudinal axis,
the magnetic system being capable of creating a magnetic field of 875 Gs in the central portion of the longitudinal axis for the length of at least 3 cm,
the source being capable of generating a uniform plasma mode having a non-uniformity of plasma density below 3% over a cross-section of the source.

4. A method of manufacturing of semiconductor devices or integrated circuits, comprising
forming on a substrate a semiconductor structure having active regions, and
forming of conducting and/or control elements having cross sectional dimensions not exceeding 100 nm,
wherein the forming of conducting and/or control elements comprises
growing at least one thin layer of dielectric on the surface of the structure,
depositing a resist layer,
performing lithography and precision etching of dielectric in the regions of conducting and/or control elements location,
sputtering metal, and
stripping resist,
wherein the precision etching and growing of the dielectric comprise
microwave frequency plasma enhancement under electron cyclotron resonance with a radio-frequency bias of the substrate in a plasma source, a reactor of the source having nonresonant volume at frequencies 2.45 and 1.23 GHz,
wherein a magnetic system generates a magnetic field of 910-940 Gs at an internal cross-section of a quarter-wave window of a microwave radiation input on the longitudinal axis of the source,
wherein the magnetic system generates a magnetic field of 875 Gs in the central portion of the longitudinal axis of the source for the length of at least 3 cm, and
wherein a uniform plasma mode has a non-uniformity of plasma density below 3% over a cross-section of the source.

5. The method of claim 4, wherein
a layer of dielectric is a layer of silicon nitride grown at the substrate temperature of 20-300° C. from a mixture of monosilane and nitrogen using overdense cold plasma, the precision etching is performed at the substrate temperature of 77-400 K using overdense cold plasma in the medium of halogen-containing gases,
a control element is a T-shaped gate, and
conducting elements are T-shaped conductors or microstrip lines.

6. The method of claim 5, wherein forming a T-shaped transistor gate comprises
growing a silicon nitride layer 100-120 nm thick on GaAs,
depositing a PNIMA resist layer 0.1-0.4 micron thick,
performing a first electron-beam lithography to form regions of sub-100 nm part of the gate,
ECR plasma etching of silicon nitride in a mixture of CF₄ and Ar or fluorine, at a flow rate of CF₄ or fluorine of 10-100 cm³/min and a flow rate of Ar of 10-50 cm³/min, at the total
pressure within the reactor of 1-7 mTorr,
depositing a second resist layer
performing a second electron-beam lithography to form regions of the upper part of the gate having cross-sectional dimension in plane of 600 nm,
wet etching of transistor channel, and
forming a Ti/Pt/Au metallization.

7. The method of claim 5, wherein forming a T-shaped conductor comprises
depositing a polyimide layer 50-250 nm thick on the substrate with active elements,
growing a silicon nitride layer 100-120 nm thick on the substrate,
depositing PMMA resist layer 00.4 micron thick
performing a first electron-beam lithography to form regions of sub-100 nm part of the conductor,
ECR-plasma etching of silicon nitride in a mixture of CF₄ and Ar or fluorine, at a flow rate of CF₄ or fluorine of 10-100 cm³/min and a flow rate of Ar of 10-50 cm³/min at a total pressure within the reactor of 1-7 mToff,
depositing a second resist layer,
performing a second electron-beam lithography to form regions of the upper part of the conductor having cross-sectional dimension in plane of 600 nm,
forming a Ti/Pt/Au metallization, and
wet or ECR-plasma stripping of silicon nitride and polyimide.

8. A method of manufacturing of semiconductor devices or integrated circuits having suspended microstructure, wherein forming at least one element of the device or circuit comprises
gorwing a thin layer of dielectric on a substrate at a low temperature,
depositing an electron-beam- or photoresist, and
lithography process and precision etching of the dielectric,
wherein the precision etching of the dielectric and growing of the dielectric comprise
microwave frequency plasma enhancement under electron cyclotron resonance with a radio-frequency bias of the substrate in a plasma source, a reactor of the source having nonresonant volume at frequencies 2.45 and 1.23 GHz,
wherein a magnetic system generates a magnetic field of 910-940 Gs at an internal cross-section of a quarter-wave window of a microwave radiation input on the longitudinal axis of the source,
wherein the magnetic system generates a magnetic field of 875 Gs in the central portion of the longitudinal axis of the source for the length of at least 3 cm, and
wherein a uniform plasma mode has a non-uniformity of plasma density below 3% over a cross-section of the source.

9. The method of claim 8, wherein forming suspended microstructures of uncooled bolometric matrices comprises
depositing a polyimide layer 1-3 micron thick on the substrate,
growing a silicon nitride layer from a mixture of monosilane and nitrogen using overdense cold plasma under electron cyclotron resonance at substrate temperature 293-573 K, the silicon nitride layer being a dielectric layer,
depositing a heat-sensitive material layer,
performing a electron-beam or photolithography, and
precision etching using overdense cold plasma under electron cyclotron resonance at a substrate temperature of 77-400 K with a radio-frequency bias of the substrate in a medium comprising halogen-containing gases and oxygen,
sputtering metals, and
stripping the resist,
wherein the depositing of the layers and etching are performed in an ultra-high-vacuum ECR-plasma unit.

10. The method of claim 8, wherein forming air bridges of interconnections between microwave transistors and integrated circuits comprises
depositing a polyimide layer 0.2-3 micron thick,
electron-beam or photolithography,
precision etching of polyimide surface to form a predetermined pattern using overdense cold plasma under electron cyclotron resonance at a substrate temperature of 77-400 K with a radio-frequency bias of the substrate in the medium of halogen-containing gases and oxygen, growing a silicon nitride layer from a mixture of monosilane and nitrogen using overdense cold plasma under electron cyclotron resonance at a substrate temperature of 293-573 K,
depositing a metal layer,
electron-beam or photolithography, and
precision etching using overdense cold plasma under electron cyclotron resonance at a substrate temperature of 77-400 K with a radio-frequency bias of the substrate in a medium comprising halogen-containing gases and oxygen,
wherein the deposition of the layers and etching are performed in an ultra-high-vacuum ECR-plasma unit.

11. The method of claim 8, wherein forming tuning elements of microwave transistors, solid-state or hybrid integrated circuits comprises
depositing a polyimide layer 0 3 micron thick on the substrate,
electron-beam or photolithography,
precision etching of the polyimide surface to form a predetermined pattern using overdense cold plasma under electron cyclotron resonance at a substrate temperature of 77-400 K with a radio-frequency bias of the substrate in a medium comprising halogen-containing gases and oxygen,
growing a silicon nitride layer from a mixture of monosilane and nitrogen using overdense cold plasma under electron cyclotron resonance at a substrate temperature of 293-573 K,
depositing a metal layer,
electron-beam or photolithography, and
precision etching using overdense cold plasma under electron cyclotron resonance at a substrate temperature of 77-400 K with a radio-frequency bias of the substrate in a medium comprising halogen-containing gases and oxygen,
wherein the deposition of the layers and etching are performed in an ultra-high-vacuum ECR-plasma unit, and
the elements are tuned by changing a voltage between the substrate and an upper conductor layer, a distance between the substrate and the upper conductor being changed by Coulomb forces, to establish a necessary impedance of the transistor tract or of the integrated circuit node.

12. A method of manufacturing of semiconductor devices or integrated circuits, comprising
forming on a substrate of a semiconductor structure comprising active regions, isolation regions, metallization and passivating coating,
wherein the forming of the passivating coating comprises
growing at least one thin layer of dielectric on a surface of the structure,
wherein the growing of the dielectric comprises
microwave frequency plasma enhancement under electron cyclotron resonance with a radio-frequency bias of the substrate in a plasma source, a reactor of the source
having nonresonant volume at frequencies 2.45 and 1.23 GHz,
wherein a magnetic system generates a magnetic field of 910-940 Gs at an internal cross-section of a quarter-wave window of a microwave radiation input on the longitudinal axis of the source,
wherein the magnetic system generates a magnetic field of 875 Gs in the central portion of the longitudinal axis of the source for the length of at least 3 cm, and
wherein a uniform plasma mode has a non-uniformity of plasma density below 3% over a cross-section of the source.

13. The method of claim 12, wherein the semiconductor device or integrated circuit is a microwave device having the structure based on group A_{III}B_{V} compounds, wide-gap AlGaN semiconductor compounds, or SiC.

14. The method of claim 12, wherein a passivating layer of dielectric is a silicon nitride layer is grown from a mixture of monosilane and nitrogen at a temperature of 293-573 K using overdense cold plasma, the hydrogen bonds content (Si—H and N—H) being maintained in the range of 4-15%, and self-biasing voltage being maintained in the range of 0-50 V.

15. A semiconductor device or integrated circuit comprising
conducting and/or control elements having cross-sectional dimensions in plane not exceeding 100 nm,
the elements being produced by a method comprising
forming on a substrate a semiconductor structure with active regions,
forming the conducting and/or control elements having cross-sectional dimensions not exceeding 100 nm in plane,
growing a thin layer of dielectric on a surface of the structure to form the conducting and/or control elements,
depositing a resist layer,
lithography and precision etching of dielectric at the locations of the conducting and/or control elements,
sputtering of a metal, and
stripping of the resist,
wherein the precision etching and growing of the dielectric comprises
microwave frequency plasma enhancement under electron cyclotron resonance with a radio-frequency bias of the substrate in a plasma source, a reactor of the source having nonresonant volume at frequencies 2.45 and 1.23 GHz,
wherein a magnetic system generates a magnetic field of 910-940 Gs at an internal cross-section of a quarter-wave window of a microwave radiation input on the longitudinal axis of the source,
wherein the magnetic system generates a magnetic field of 875 Gs in the central portion of the longitudinal axis of the source for the length of at least 3 cm, and
wherein a uniform plasma mode has a non-uniformity of plasma density below 3% over a cross-section of the source.

16. The semiconductor device or integrated circuit of claim 15, wherein
the control element is a T-shaped gate and/or the conducting elements are T-shaped conductors or microstrip lines,
the dielectric layer is a silicon nitride layer 100-120 nin thick, grown at a substrate temperature of 293-573 K from a mixture of monosilane and nitrogen using overdense cold plasma, and
the locations of the conducting and/or control elements in the dielectric are formed by precision etching at a substrate temperature of 77-100 K using overdense cold plasma in a medium comprising halogen-containing gases.

17. A semiconductor device or integrated circuit comprising
a suspended microstructure produced by a method of forming at least one element of device or circuit comprising
growing at least one thin layer of dielectric on a substrate at a low temperature,
depositing an electron-beam or photoresist, and
lithography and precision etching of the dielectric,
wherein the precision etching and growing of the dielectric comprises
microwave frequency plasma enhancement under electron cyclotron resonance with a radio-frequency bias of the substrate in a plasma source, a reactor of the source having nonresonant volume at frequencies 2.45 and 1.23 GHz,
wherein a magnetic system generates a magnetic field of 910-940 Gs at an internal cross-section of a quarter-wave window of a microwave radiation input on the longitudinal axis of the source,
wherein the magnetic system generates a magnetic field of 875 Gs in the central portion of the longitudinal axis of the source for the length of at least 3 cm, and
wherein a uniform plasma mode has a non-uniformity of plasma density below 3% over a cross-section of the source.

18. The semiconductor device or integrated circuit of claim 17, wherein a layer of dielectric is a polyimide layer.

19. The semiconductor device or integrated circuit of claim 17, capable of functioning as an uncooled bolometric matrix, microwave transistor, or microwave integrated circuit.

20. A method of treatment of semiconductor structures, comprising
etching at least one structure layer using a microwave frequency ECR-plasma source,
the ECR-plasma source comprising
a reactor and
a magnetic system,
the reactor having a non-resonant volume at the frequency of 2.45 and 1.23 GHz,
the reactor being capable of maintaining a stable discharge,
the source having a longitudinal axis,
the magnetic system being capable of creating a magnetic field of 910-940 Gs at an internal cross-section of the quarter-wave window on the longitudinal axis,
the magnetic system being capable of creating a magnetic field of 875 Gs in the central portion of the longitudinal axis for the length of at least 3 cm,
the source being capable of generating a uniform plasma mode having a non-uniformity of plasma density below 3% over a cross-section of the source.
